(19) United States
(12) Patent Application Publication
(10) Pub. No.: US 2025/0253822 A1
(43) Pub. Date: Aug. 7, 2025

(54) ELECTRONIC DEVICE

(71) Applicant: VIA LABS, INC., New Taipei City (TW)

(72) Inventor: Did-Min SHIH, New Taipei City (TW)

(21) Appl. No.: 19/189,371

(22) Filed: Apr. 25, 2025

Related U.S. Application Data
(63) Continuation-in-part of application No. 18/401,900, filed on Jan. 2, 2024.
(60) Provisional application No. 63/518,088, filed on Aug. 7, 2023.

(30) Foreign Application Priority Data
Oct. 13, 2023 (TW) 112139136

(51) Int. Cl. H03H 7/38; H03K 17/51

(52) U.S. Cl. CPC H03H 7/38; H03K 17/51

(57) ABSTRACT

An electronic device includes a common pin pair and a bandwidth expansion circuit. The electronic device receives or transmits a signal through the common pin pair. The signal is a differential signal. The bandwidth expansion circuit is electrically coupled to the common pin pair. The bandwidth expansion circuit includes a first inductor pair electrically connected between the common pin pair and a node pair, a second inductor pair electrically connected to the first inductor pair through the node pair, a first capacitor pair electrically connected between the node pair and a ground end, a second capacitor pair electrically connected the common pin pair and the ground end, and a third capacitor pair electrically connected between the second inductor pair and the ground end. The first and second inductor pair both include two inductors. The two inductors have a coupling effect.

### CROSS REFERENCE TO RELATED APPLICATIONS

This application is a Continuation-In-Part of pending U.S. patent application Ser. No. 18/401,900, filed Jan. 2, 2024 and entitled “ELECTRONIC DEVICE”, which claims priority of Taiwan Patent Application No. 112139136 filed on Oct. 13, 2023, and the benefit of U.S. Provisional Application Ser. No. 63/518,088, filed on Aug. 7, 2023, the entirety of which is incorporated by reference herein.

This application claims priority of Taiwan Patent Application No. 113214165 filed on Dec. 24, 2024, the entirety of which is incorporated by reference herein.

### BACKGROUND OF THE INVENTION

### Field of the Invention

The present invention relates to an electronic device, and, in particular, to an electronic device used to improve an impedance matching bandwidth of common pins.

### Description of the Related Art

In existing integrated circuit (IC) designs, T-coil circuits are often used to increase the bandwidth of circuits, and nodes in two inductors in the T-coil circuit are often used to directly electrically connect to the receiving circuit and the transmitting circuit. However, since the nodes in the two inductors in the T-coil circuit are connected to the receiving circuit and the transmitting circuit at the same time, parasitic capacitances of the receiving circuit and the transmitting circuit themselves will all be superimposed on the nodes, causing equivalent capacitances connected to the nodes to increase, causing the bandwidth to become smaller, or the increased bandwidth to be limited.

### BRIEF SUMMARY OF THE INVENTION

An embodiment of the present invention provides an electronic device. The electronic device includes a common pin pair and a bandwidth expansion circuit. The electronic device receives or transmits a signal through the common pin pair. The signal is a differential signal. The bandwidth expansion circuit is electrically coupled to the common pin pair. The bandwidth expansion circuit includes a first inductor pair, a second inductor pair, a first capacitor pair, a second capacitor pair, and a third capacitor pair. The first inductor pair is electrically connected between the common pin pair and a node pair. The second inductor pair is electrically connected to the first inductor pair through the node pair. The first capacitor pair is electrically connected between the node pair and a ground end. The second capacitor pair is electrically connected to the common pin pair and the ground end. The third capacitor pair is electrically connected between the second inductor pair and the ground end. The first inductor pair includes a first inductor and a second inductor. The second inductor pair includes a third inductor and a fourth inductor. There is a coupling effect between the first inductor and the second inductor. There is a coupling effect between the third inductor and the fourth inductor.

The electronic device further includes a high-frequency impedance matching circuit. The high-frequency impedance matching circuit is electrically connected between the common pin pair and the bandwidth expansion circuit. The high-frequency impedance matching circuit includes a third inductor pair, a fourth capacitor pair, a fifth capacitor pair, a first resistor pair, and a second resistor pair. The third inductor pair is electrically connected between the common pin pair and the bandwidth expansion circuit. The fourth capacitor pair is electrically connected to one side of the third inductor pair. The fifth capacitor pair is electrically connected to the other side of the third inductor pair. The first resistor pair is electrically connected between the fourth capacitor pair and the ground end. The second resistor pair is electrically connected between the fifth capacitor pair and the ground end. The third inductor pair includes a fifth inductor and a sixth inductor. There is a coupling effect between the fifth inductor and the sixth inductor.

The electronic device further includes a switch pair and a terminal resistor pair. The switch pair is electrically connected to the second inductor pair. The terminal resistor pair is electrically connected between the switch pair and the ground end. When the electronic device receives the signal through the common pin pair, the switch pair is turned on. When the electronic device transmits the signal through the common pin pair, the switch pair is turned off.

The electronic device further includes a receiving circuit. The receiving circuit is electrically connected to the node pair. The receiving circuit receives the signal from the common pin pair.

The electronic device further includes a transmitting circuit. The transmitting circuit is electrically connected to the second inductor pair. The transmitting circuit transmits the signal to the common pin pair.

According to the electronic device described above, the first inductor generates an equivalent inductance based on the coupling effect, and the equivalent inductance is obtained by the following equation: L_{eff1}=L₁* (1+kₛ₁). L_{eff1} is the equivalent inductance, L₁ is the inductance of the first inductor, and kₛ₁ is the coupling coefficient between the first inductor and the second inductor. The coupling coefficient is greater than zero.

According to the electronic device described above, the first capacitor pair includes a parasitic capacitance generated when the receiving circuit is electrically connected to the node pair.

According to the electronic device described above, the third capacitor pair includes a parasitic capacitance generated when the transmitting circuit is electrically connected to the second inductor pair.

According to the electronic device described above, the first capacitor pair includes a parasitic capacitance generated when electrostatic discharge (ESD) diodes are respectively electrically connected to the node pair.

According to the electronic device described above, the node pair is a pair of pins in a semiconductor package. The semiconductor package includes a semiconductor chip.

According to the electronic device described above, the node pair is a pair of pins in the semiconductor chip. The first inductor pair and the second inductor pair are bonding wires for electrically connecting to the common pin pair

According to the electronic device described above, the signal includes a high-frequency component signal and a low-frequency component signal. When the electronic device receives the signal through the common pin pair, the high-frequency component signal terminates at the first resistor pair, and the low-frequency component signal terminates at the terminal resistor pair.

### BRIEF DESCRIPTION OF THE DRAWINGS

The present invention can be more fully understood by reading the subsequent detailed description and examples with references made to the accompanying drawings, wherein:

FIG. 1 shows a schematic diagram of an electronic device 100 in accordance with some embodiments of the present invention;

FIG. 2 shows a schematic diagram of a T-coil 200 in the prior art;

FIG. 3 shows a schematic diagram of an electronic device 300 in accordance with some embodiments of the present invention;

FIG. 4 shows a schematic diagram of an inductor pair including an inductor LP and an inductor LN in accordance with some embodiments of the present invention;

FIG. 5A shows a graph of a return loss S11 and a penetration loss S21 of the T-coil 200 in the prior art.

FIG. 5B shows a graph of a return loss S11 and a penetration loss S21 of the electronic device 100 in FIG. 1 and the electronic device 300 in FIG. 3 in accordance with some embodiments of the present invention.

### DETAILED DESCRIPTION OF THE INVENTION

In order to make the above purposes, features, and advantages of some embodiments of the present invention more comprehensible, the following is a detailed description in conjunction with the accompanying drawing.

Certain terms are used throughout the description and following claims to refer to particular components. As one skilled in the art will understand, electronic equipment manufacturers may refer to a component by different names. This document does not intend to distinguish between components that differ in name but not function. It is understood that the words “comprise”, “have” and “include” are used in an open-ended fashion, and thus should be interpreted to mean “include, but not limited to . . . ”. Thus, when the terms “comprise”, “have” or “include” used in the present invention are used to indicate the existence of specific technical features, values, method steps, operations, units or components. However, it does not exclude the possibility that more technical features, numerical values, method steps, work processes, units, components, or any combination of the above can be added.

The directional terms used throughout the description and following claims, such as: “on”, “up”, “above”, “down”, “below”, “front”, “rear”, “back”, “left”, “right”, etc., are only directions referring to the drawings. Therefore, the directional terms are used for explaining and not used for limiting the present invention. Regarding the drawings, the drawings show the general characteristics of methods, structures, or materials used in specific embodiments. However, the drawings should not be construed as defining or limiting the scope or properties encompassed by these embodiments. For example, for clarity, the relative size, thickness, and position of each layer, each area, or each structure may be reduced or enlarged.

When the corresponding component such as layer or area is referred to as being “on another component”, it may be directly on this other component, or other components may exist between them. On the other hand, when the component is referred to as being “directly on another component (or the variant thereof)”, there is no component between them. Furthermore, when the corresponding component is referred to as being “on another component”, the corresponding component and the other component have a disposition relationship along a top-view/vertical direction, the corresponding component may be below or above the other component, and the disposition relationship along the top-view/vertical direction is determined by the orientation of the device.

It should be understood that when a component or layer is referred to as being “connected to” another component or layer, it can be directly connected to this other component or layer, or intervening components or layers may be present. In contrast, when a component is referred to as being “directly connected to” another component or layer, there are no intervening components or layers present.

The electrical connection or coupling described in this disclosure may refer to direct connection or indirect connection. In the case of direct connection, the endpoints of the components on the two circuits are directly connected or connected to each other by a conductor line segment, while in the case of indirect connection, there are switches, diodes, capacitors, inductors, resistors, other suitable components, or a combination of the above components between the endpoints of the components on the two circuits, but the intermediate component is not limited thereto.

The words “first”, “second”, and “third” are used to describe components. They are not used to indicate the priority order of or advance relationship, but only to distinguish components with the same name.

It should be noted that the technical features in different embodiments described in the following can be replaced, recombined, or mixed with one another to constitute another embodiment without depart in from the spirit of the present invention.

In the implementation of integrated circuits (ICs), an electrostatic discharge (ESD) protection circuit is generally used to prevent static electricity from causing damage to the IC. However, the ESD protection circuit contains parasitic capacitance, which reduces the bandwidth of the IC's output/input port circuit, thus affecting the quality of the IC's receiving and transmitting signals. In the past, T-coil circuits were used to absorb the parasitic capacitance of the ESD protection circuit to extend the bandwidth of the output/input (I/O) port circuit with the ESD protection circuit.

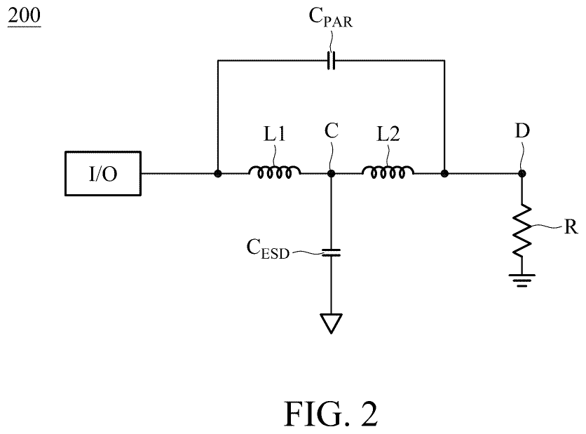

FIG. 2 shows a schematic diagram of a T-coil 200 in the prior art. As shown in FIG. 2, the T-coil 200 includes an input and output port I/O, an inductor L1, an inductor L2, a capacitor C_{ESD}, a capacitor C_{PAR}, and a terminal resistor R. The inductor L1 is electrically connected between a node C and the input and output port I/O. The inductor L2 is electrically connected between the node C and a node D. The capacitor C_{PAR} is electrically connected between the node C and the ground end. The capacitor C_{PAR} is electrically connected across the inductor L1 and the inductor L2. The terminal resistor R is electrically connected to the node D and the ground end. The T-coil 200 is a traditional T-coil circuit.

In FIG. 2, the capacitor C_{PAR} is a parasitic capacitance between the inductor L1 and inductor L2. The capacitor C_{ESD} is a parasitic capacitance generated when electrostatic discharge diodes are connected to the node C. The electrostatic discharge diodes are used to protect against electrostatic pulses from the input and output port I/O. In the application of the traditional T-coil circuit, when the T-coil circuit is used as a half-duplex transmission, the receiving circuit and the transmitting circuit are both electrically connected to the node C, so the capacitor C_{ESD} will include the parasitic capacitance generated when the receiving circuit and the transmitting circuit are electrically connected to the node C. Although the T-coil 200 also has the function of amplifying the bandwidth of the entire transmission line, for example, amplifying it to 3 times the original value, due to the influence of the parasitic capacitance generated when the transmitting circuit and the receiving circuit are connected to the T-coil circuit at the same time, the high-frequency response of the entire transmission line becomes worse, making the basic bandwidth of the entire transmission line smaller, thereby reducing the efficiency of the T-coil circuit in amplifying the bandwidth.

Furthermore, in the traditional T-coil 200 in FIG. 2, the node C is the contact point for receiving/transmitting signals, and the node D is used to terminate the characteristic impedance to achieve impedance matching. However, since there is an all-pass transfer function from the output/input port circuit to the node D, this all-pass transfer function contains zeros on the right half plane, so it is not suitable for serial data transmission (SerDes) applications. Therefore, when the receiving circuit and the transmitting circuit are both connected at the node C, although only the receiving circuit or the transmitting circuit is turned on each time, the other transmitting circuit or receiving circuit that is turned off increases the capacitive load at the node C, thus reducing the bandwidth. In order to allow the output/input port circuit to the node D to be used for serial data transmission, this invention will eliminate the coupling effect between the inductor LP1 and the inductor LP2. Therefore, there will no longer be an all-pass transfer function from the output/input port circuit to the node D. Therefore, the node D can also be connected to the receiving circuit or the transmitting circuit. That is, the nodes C and D can be connected to the receiving circuit or transmitting circuit respectively. Therefore, this invention does not need to connect the receiving circuit and/or transmitting circuit to the node C at the same time, which will reduce the original capacitive load at the node C, thus improving the bandwidth. Therefore, the electronic device 100 with the high-frequency impedance matching circuit 106 and the electronic device 300 with the high-frequency impedance matching circuit 306 of the present invention are designed. In order to improve the return loss of the output/input port circuit, an additional high-frequency impedance matching circuit is added, which will be explained below.

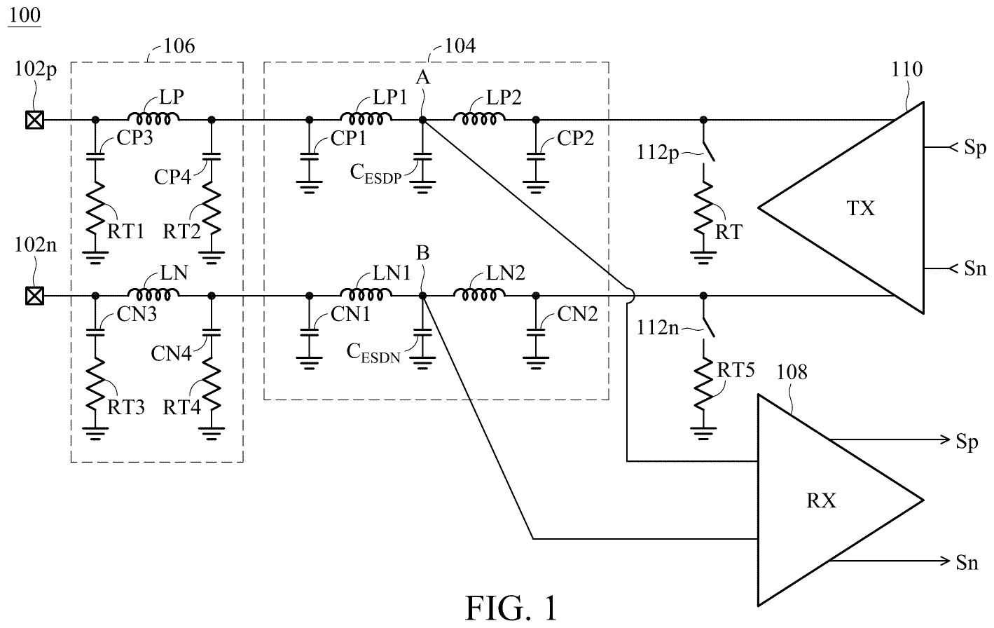

FIG. 1 shows a schematic diagram of an electronic device 100 in accordance with some embodiments of the present invention. As shown in FIG. 1, the electronic device 100 includes a common pin 102p, a common pin 102n, a bandwidth expansion circuit 104, a high-frequency impedance matching circuit 106, a receiving circuit 108, a transmitting circuit 110, a switch 112p, a switch 112n, a terminal resistor RT, and a terminal resistor RT5. In some embodiments, the electronic device 100 receives or transmits a signal through the common pin 102p and the common pin 102n. In some embodiments of FIG. 1, the signal may be, for example, a differential signal. For example, the signal may include a positive phase signal Sp and an inverted phase signal Sn. The common pin 102p is used to receive or transmit the positive phase signal Sp in the signal. The common pin 102n is used to receive or transmit the inverted signal Sn in the signal.

However, the present invention does not limit the signal to be the differential signal. For example, if the signal is not the differential signal, the electronic device 100 only needs to receive or transmit the signal through one of the common pin 102p and the common pin 102n. In some embodiments, the electronic device 100 may be, for example, a semiconductor package. The common pin 102p may be, for example, a pin of the semiconductor package. The common pin 102n may be, for example, another pin of the semiconductor package. In some embodiments, semiconductor packaging can utilize any existing packaging technology in the industry, such as Wafer Level Chip Scale Package (WLCSP), Chip on Flex (COF), Chip on Glass (COG), and Chip on Plastic (COP).

In some embodiments of FIG. 1, the bandwidth expansion circuit 104 is electrically coupled to the common pin 102p and the common pin 102n. In detail, the bandwidth expansion circuit 104 is electrically coupled to the common pin 102p and the common pin 102n through the high-frequency impedance matching circuit 106. In some embodiments of FIG. 1, the bandwidth expansion circuit 104 includes an inductor LP1, an inductor LP2, a capacitor C_{ESDP}, a capacitor CP1, and a capacitor CP2. The high-frequency impedance matching circuit 106 includes an inductor LP, a capacitor CP3, a capacitor CP4, a resistor RT1, and a resistor RT2. In some embodiments, the inductor LP1 is electrically connected between the common pin 102p (or the inductor LP) and a node A. The inductor LP2 is electrically connected to the inductor LP1 through node A. The capacitor C_{ESDP} is electrically connected between the node A and the ground end. The capacitor CP1 is electrically connected between the common pin 102p (or the inductor LP) and the ground end. The capacitor CP2 is electrically connected between the inductor LP2 and the ground end.

In some embodiments, the inductor LP1 is different from inductor LP2. There is no coupling effect between the inductor LP1 and the inductor LP2. In some embodiments, there is no mutual inductance between the inductor LP1 and the inductor LP2, or the mutual inductance between the inductor LP1 and the inductor LP2 should be reduced as much as possible. In other words, magnetic field lines generated by the inductor LP1 do not intersect with magnetic field lines generated by the inductor LP2. In some embodiments, viewed from a top view, the angle between the inductor LP1 and the inductor LP2 can be 90 degrees, but the present invention is not limited thereto. In some embodiments, the semiconductor package includes a semiconductor chip. The semiconductor chip may include the bandwidth expansion circuit 104, for example. The node A is a pin of the semiconductor chip. The inductor LP1 and the inductor LP2 are bonding wires for electrically connecting to the common pin 102p.

In some embodiments, the capacitor C_{ESDP} in the bandwidth expansion circuit 104 includes a parasitic capacitance generated when an electrostatic discharge (ESD) diode is connected to the node A. The ESD diode is used to protect against electrostatic pulses from the common pin 102p. The capacitor CP1 and the capacitor CP2 are parasitic capacitances generated between layers in the semiconductor chip, and/or parasitic capacitances generated by adjacent wires in the circuit layout of the semiconductor chip.

In some embodiments of FIG. 1, the high-frequency impedance matching circuit 106 includes an inductor LP, a capacitor CP3, a capacitor CP4, a resistor RT1, and a resistor RT2. In some embodiments, the inductor LP is electrically connected between the common pin 102p and the inductor LP1. The capacitor CP3 is electrically connected to one side of the inductor LP. The capacitor CP4 is electrically connected to the other side of the inductor LP. The resistor RT1 is electrically connected between the capacitor CP3 and the ground end. The resistor RT2 is electrically connected between the capacitor CP4 and the ground end. In some embodiments, the switch 112p is electrically connected to the inductor LP2 and the capacitor CP2. The terminal resistor RT is electrically connected between the switch 112p and the ground end. When the electronic device 100 receives the signal through the common pin 102p, the switch 112p is turned on. On the other hand, when the electronic device 100 transmits the signal through the common pin 102p, the switch 112p is turned off.

When the signal is the differential signal, the bandwidth expansion circuit 104 further includes an inductor LN1, an inductor LN2, a capacitor C_{ESDN}, a capacitor CN1, and a capacitor CN2. The high-frequency impedance matching circuit 106 further includes an inductor LN, a capacitor CN3, a capacitor CN4, a resistor RT3, and a resistor RT4. In some embodiments, the inductor LN1 is electrically connected between the common pin 102n (or the inductor LN) and the node B. Inductor LN2 is electrically connected to the inductor LN1 through the node B. The capacitor C_{ESDN} is electrically connected between the node B and the ground end. The capacitor CN1 is electrically connected between the common pin 102n (or the inductor LN) and the ground end. The capacitor CN2 is electrically connected between the inductor LN2 and the ground end.

In some embodiments, the inductor LN1 is different from the inductor LN2, and there is no coupling effect between the inductor LN1 and the inductor LN2. In some embodiments, there is no mutual inductance between the inductor LN1 and the inductor LN2, or the mutual inductance between the inductor LN1 and the inductor LN2 is reduced as much as possible. In other words, magnetic field lines generated by the inductor LN1 do not intersect with magnetic field lines generated by the inductor LN2. In some embodiments, viewed from a top view, the angle between the inductor LN1 and the inductor LN2 can be 90 degrees, but the present invention is not limited thereto. In some embodiments, the node B is a pin of the semiconductor chip. The inductor LN1 and the inductor LN2 are bonding wires electrically connected to the common pin 102n.

In some embodiments, the capacitor C_{ESDN} in the bandwidth expansion circuit 104 includes the parasitic capacitance generated when the electrostatic discharge diode is connected to the node B. The electrostatic discharge diode is used to protect against electrostatic pulses from the common pin 102n. The capacitor CN1 and the capacitor CN2 are parasitic capacitances generated between layers in the semiconductor chip, and/or parasitic capacitances generated by adjacent wires in the circuit layout of the semiconductor chip.

When the signal is the differential signal, the high-frequency impedance matching circuit 106 further includes an inductor LN, a capacitor CN3, a capacitor CN4, a resistor RT3, and a resistor RT4. In some embodiments, the inductor LN is electrically connected between the common pin 102n and the inductor LN1. The capacitor CN3 is electrically connected to one side of the inductor LN. The capacitor CN4 is electrically connected to the other side of the inductor LN. The resistor RT3 is electrically connected between the capacitor CN3 and the ground end. The resistor RT4 is electrically connected between the capacitor CN4 and the ground end. In some embodiments, the switch 112n is electrically connected to the inductor LN2 and the capacitor CN2. The terminal resistor RT5 is electrically connected between the switch 112n and the ground end. When the electronic device 100 receives the signal through the common pin 102n, the switch 112n is turned on. On the other hand, when the electronic device 100 transmits the signal through the common pin 102n, the switch 112n is turned off.

When the signal is the differential signal, the signal may include a positive phase signal Sp and an inverted phase signal Sn. The common pin 102p is used to receive or transmit the positive phase signal Sp in the signal. The common pin 102n is used to receive or transmit the inverted signal Sn in the signal. In some embodiments, the receiving circuit (RX) 108 is electrically connected to the node A and the node B, and is used for receiving the signal from the common pin 102p and the common pin 102n (for example, including the positive phase signal Sp and the inverted phase signal Sn). The transmitting circuit (TX) 110 is electrically connected to the inductor LP2 and the inductor LN2 for transmitting the signal (for example, including the positive phase signal Sp and the inverted phase signal Sn) to the common pin 102p and the common pin 102n.

In some embodiments, the capacitor C_{ESDP} and the capacitor C_{ESDN} not only include the parasitic capacitance generated when the electrostatic discharge diodes are connected to the nodes A and B, but also include the parasitic capacitance generated when the receiving circuit 108 is electrically connected to the nodes A and B. In some embodiments, the capacitor CP2 and the capacitor CN2 not only include the parasitic capacitance generated between layers in the semiconductor chip, and/or the parasitic capacitance generated by adjacent wires in the circuit layout of the semiconductor chip, but also include the parasitic capacitance generated when the transmitting circuit 110 is electrically connected to the inductor LP2 and the inductor LN2.

When the signal is the differential signal, the positive phase signal Sp and the inverted phase signal Sn include a high-frequency component signal and a low-frequency component signal respectively. In the actual circuit application in FIG. 1, when the electronic device 100 receives the positive phase signal Sp and the inverted phase signal Sn through the common pin 102p and the common pin 102n respectively, for the high-frequency component signal, the impedance of the capacitor CP3 and the capacitor CN3 is extremely small (equivalent to a short circuit), and the impedance of the inductor LP and the inductor LN is extremely large (equivalent to an open circuit). The high-frequency component signal in the positive-phase signal Sp and the inverted phase signal Sn will pass through the capacitor CP3 and the capacitor CN3, and thus terminate at the resistor RT1 and resistor RT3. Therefore, the high-frequency impedance matching circuit 106 can effectively improve the frequency response of the electronic device 100 when transmitting the high-frequency component signal.

Similarly, when the electronic device 100 receives the positive phase signal Sp and the inverted phase signal Sn through the common pin 102p and the common pin 102n respectively, for the low-frequency component signal, the impedance of the capacitor CP3, capacitor CN3, the capacitor CP4, the capacitor CN4, the capacitor CP1, the capacitor CN1, the capacitor C_{ESDP}, the capacitor C_{ESDN}, the capacitor CP2, and the capacitor CN2 is extremely large (equivalent to an open circuit), and the impedance of the inductor LP, the inductor LN, the inductor LP1, the inductor LN1, the inductor LP2, and the inductor LN2 is extremely small (equivalent to a short circuit). The low-frequency component signal in the positive phase signal Sp and the inverted phase signal Sn will first pass through the inductor LP, the inductor LN, the inductor LP1, the inductor LN1, the inductor LP2, the inductor LN2, and then pass through the switch 112p and the switch 112n (the switch 112p and the switch 112n are both turned on), and thus terminate at the terminal resistor RT and the terminal resistor RT5. Therefore, the frequency response of the electronic device 100 when transmitting the low-frequency component signal is still very good.

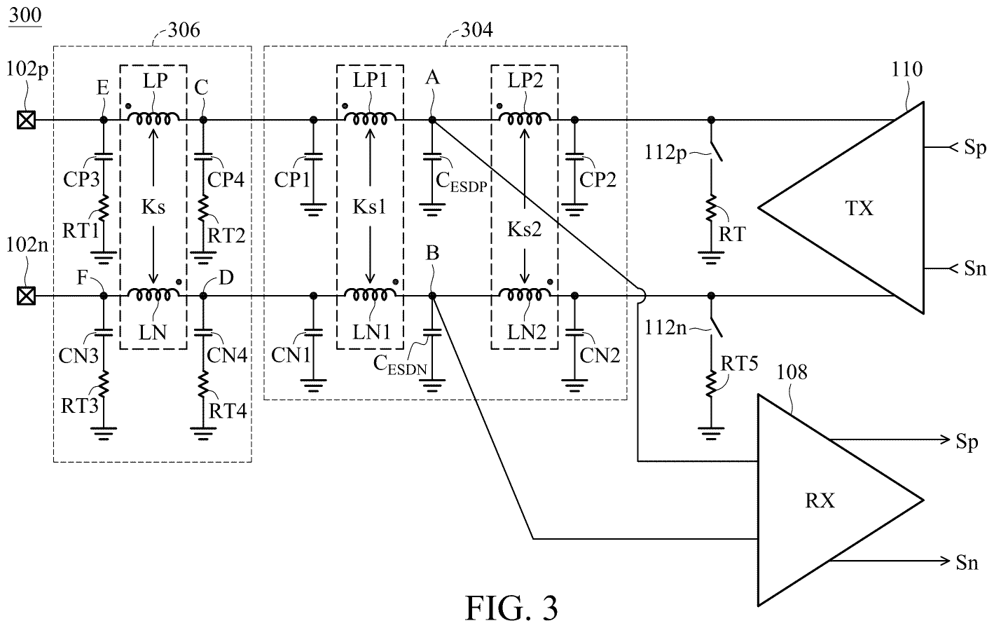

FIG. 3 shows a schematic diagram of an electronic device 300 in accordance with some embodiments of the present invention. The main difference between the electronic device 300 and the electronic device 100 is that the electronic device 300 uses multiple sets of inductor pairs that have coupling effects with each other. As shown in FIG. 3, the electronic device 300 includes a common pin pair (including a common pin 102p and a common pin 102n), a bandwidth expansion circuit 304, a high-frequency impedance matching circuit 306, a receiving circuit 108, a transmitting circuit 110, a switch pair (including a switch 112p and a switch 112n), and a terminal resistor pair (including a terminal resistor RT and a terminal resistor RT5). In some embodiments, the electronic device 300 receives or transmits a signal through a common pin pair (including the common pin 102p and the common pin 102n). In some embodiments of FIG. 3, the signal is a differential signal. For example, the signal may include a positive phase signal Sp and an inverted phase signal Sn. The common pin 102p is used to receive or transmit the positive phase signal Sp in the signal. The common pin 102n is used to receive or transmit the inverted signal Sn in the signal. In some embodiments, the electronic device 300 may be, for example, a semiconductor package. The common pin pair (including the common pin 102p and the common pin 102n) may be, for example, a pair of pins in the semiconductor package. In some embodiments, semiconductor packaging can utilize any existing packaging technology in the industry, such as Wafer Level Chip Scale Package (WLCSP), Chip on Flex (COF), Chip on Glass (COG), and Chip on Plastic (COP). In some embodiments of FIG. 3, the bandwidth expansion circuit 304 is electrically coupled to the common pin pair (including the common pin 102p and the common pin 102n). In detail, the bandwidth expansion circuit 304 is electrically coupled to the common pin 102p and the common pin 102n through the high-frequency impedance matching circuit 306. In some embodiments of FIG. 3, the bandwidth expansion circuit 304 includes a first inductor pair (including the inductor LP1 and the inductor LN1), a second inductor pair (including the inductor LP2 and the inductor LN2), a first capacitor pair (including the capacitor C_{ESDP} and the capacitor C_{ESDN}), a second capacitor pair (including the capacitor CP1 and the capacitor CN1), and a third capacitor pair (including the capacitor CP2 and the capacitor CN2).

In some embodiments of FIG. 3, the first inductor pair (including the inductor LP1 and the inductor LN1) is electrically connected between the common pin pair (including the common pin 102p and the common pin 102n) and the node pair (including the node A and the node B). The second inductor pair (including the inductor LP2 and the inductor LN2) is electrically connected to the first inductor pair through the node pair (including the node A and the node B). The first capacitor pair (including the capacitor C_{ESDP} and the capacitor C_{ESDN}) is electrically connected between the node pair and a ground end. The second capacitor pair (including the capacitor CP1 and the capacitor CN1) is electrically connected between the common pin pair and the ground end. The third capacitor pair (including the capacitor CP2 and the capacitor CN2) is electrically connected between the second inductor pair and the ground end.

In some embodiments of FIG. 3, there is a coupling effect between the inductor LP1 and the inductor LN1. For example, the coupling effect between the inductor LP1 and the inductor LN1 may be represented by a coupling coefficient kₛ₁. There is also a coupling effect between the inductor LP2 and the inductor LN2. For example, the coupling effect between the inductor LP2 and the inductor LN2 may be represented by a coupling coefficient Kₛ₂. In some embodiments, the inductor LP1 generates a first equivalent inductance based on the coupling effect (i.e., the coupling coefficient kₛ₁), and the first equivalent inductance is obtained according to the following equation: L_{eff1}=L₁*(1+kₛ₁). L_{eff1} is a first equivalent inductance. L₁ is the inductance of the inductor LP1. kₛ₁ is the coupling coefficient between the inductor LP1 and the inductor LN1. The coupling coefficient kₛ₁ is greater than zero. In some embodiments, the inductor LN1 generates a second equivalent inductance based on the coupling effect (i.e., the coupling coefficient ks1), and the second equivalent inductance is obtained according to the following equation: L_{eff2}=L₂*(1+kₛ₁). L_{eff2} is a second equivalent inductance. L₂ is the inductance of the inductor LN1. Since the coupling coefficient kₛ₁ is greater than zero, the actual inductance of the first equivalent inductance L_{eff1} corresponding to the inductor LP1 will be higher than the inductance of the inductor LP1, and the actual inductance of the second equivalent inductance L_{eff2} corresponding to the inductor LN1 will be higher than the inductance of the inductor LN1.

For example, it is assumed that in the design of the electronic device 100, the inductances of the inductor LP1 and the inductor LN1 in the bandwidth expansion circuit 104 need to be 200 nH. In the design of the electronic device 300, since there is a coupling effect (i.e., coupling coefficient kₛ₁) between the inductor LP1 and the inductor LN1, for example, the coupling coefficient kₛ₁ is 0.5 (the coupling coefficient kₛ₁ can be between 0.1 and 0.5). In order to make the first equivalent inductance corresponding to the inductor LP1 and the second equivalent inductance corresponding to the inductor LN1 to be 200 nH, the inductances of the inductor LP1 and the inductor LN1 only need to be designed as 200/(1+0.5)=133.33 nH.

Since the inductances of the inductor LP1 and the inductor LN1 in the bandwidth expansion circuit 304 are reduced from 200 nH to 133.33 nH, the layout space of the inductor LP1 and the inductor LN1 on the circuit board will also become smaller. Similarly, since the inductor LP2 and the inductor LN2 also have a coupling effect (i.e., the coupling coefficient Kₛ₂), and the coupling coefficient kₛ₂ can be between 0.1 and 0.5, compared with the bandwidth expansion circuit 104, the inductances of the inductor LP2 and the inductor LN2 in the bandwidth expansion circuit 304 can also be reduced, so that the layout space of the inductor LP2 and the inductor LN2 in the circuit board will also become smaller.

The high-frequency impedance matching circuit 306 includes a third inductor pair (including the inductor LP and the inductor LN), a fourth capacitor pair (including the capacitor CP3 and the capacitor CN3), a fifth capacitor pair (including the capacitor CP4 and the capacitor CN4), a first resistor pair (including the resistor RT1 and the resistor RT3), and a second resistor pair (including the resistor RT2 and the resistor RT4). In some embodiments of FIG. 3, the third inductor pair (including the inductor LP and the inductor LN) is electrically connected between the common pin pair (including the common pin 102p and the common pin 102n) and the first inductor pair (including the inductor LP1 and the inductor LN1). The fourth capacitor pair (including the capacitor CP3 and the capacitor CN3) is electrically connected to one side of the third inductor pair. The fifth capacitor pair (including the capacitor CP4 and the capacitor CN4) is electrically connected to the other side of the third inductor pair. The first resistor pair (including the resistor RT1 and the resistor RT3) is electrically connected between the fourth capacitor pair and the ground end. The second resistor pair (including resistor RT2 and resistor RT4) is electrically connected between the fifth capacitor pair and the ground end.

In some embodiments of FIG. 3, there is a coupling effect between the inductor LP and the inductor LN. For example, the coupling effect between the inductor LP and the inductor LN may be represented by a coupling coefficient kₛ. The inductor LP generates a third equivalent inductance based on the coupling effect (i.e., the coupling coefficient kₛ), and the third equivalent inductance is obtained according to the following equation: L_{eff3}=L₃*(1+kₛ). L_{eff3} is a third equivalent inductance. L₃ is the inductance of the inductor LP. kₛ is the coupling coefficient between the inductor LP and the inductor LN. The coupling coefficient kₛ is greater than zero. In some embodiments, the inductor LN generates a fourth equivalent inductance based on the coupling effect (i.e., the coupling coefficient kₛ), and the fourth equivalent inductance is obtained according to the following equation: L_{eff4}=L₄*(1+kₛ). L_{eff4} is a fourth equivalent inductance. L₄ is the inductance of the inductor LN. Since the coupling coefficient kₛ is greater than zero, the actual inductance of the third equivalent inductor L_{eff3} corresponding to the inductor LP will be higher than the inductance of the inductor LP, and the actual inductance of the fourth equivalent inductor L_{eff4} corresponding to the inductor LN will be higher than the inductance of the inductor LN.

For example, it is assumed that in the design of the electronic device 100, the inductances of the inductor LP and the inductor LN in the high-frequency impedance matching circuit 106 need to be 120 nH. In the design of the electronic device 300, there is a coupling effect (i.e., coupling coefficient kₛ) between the inductor LP and the inductor LN, for example, the coupling coefficient kₛ is 0.2 (the coupling coefficient kₛ can be between 0.1 and 0.5). In order to make the inductance of the third equivalent inductor corresponding to the inductor LP and the fourth equivalent inductor corresponding to the inductor LN to be 120 nH, the inductances of the inductor LP and the inductor LN only need to be designed as 120/(1+0.2)=100 nH. Since the inductances of the inductor LP and the inductor LN in the high-frequency impedance matching circuit 306 are reduced from 120 nH to 100 nH, the layout space of the inductor LP and the inductor LN in the circuit board will also become smaller.

In some embodiments of FIG. 3, the switch pair (including the switch 112p and the switch 112n) is electrically connected to the second inductor pair (including the inductor LP2 and the inductor LN2). The terminal resistor pair (including the terminal resistor RT and the terminal resistor RT5) is electrically connected between the switch pair and the ground end. In some embodiments, when the electronic device 300 receives a signal through the common pin pair (including the common pin 102p and the common pin 102n), the switch pair (including the switch 112p and the switch 112n) is turned on. When the electronic device 300 transmits the signal through the common pin pair, the switch pair is turned off. In some embodiments of FIG. 3, the receiving circuit 108 is electrically connected to a node pair (including the node A and the node B) for receiving the signal from the common pin pair. The transmitting circuit 110 is electrically connected to the second inductor pair (including the inductor LP2 and the inductor LN2) for transmitting the signal to the common pin pair.

In some embodiments of FIG. 3, the first capacitor pair (including the capacitor C_{ESDP} and the capacitor C_{ESDN}) includes the parasitic capacitance generated when the receiving circuit 108 is electrically connected to the node pair (including the node A and the node B). The third capacitor pair (including the capacitor CP2 and the capacitor CN2) includes the parasitic capacitance generated when the transmitting circuit 110 is electrically connected to the second inductor pair (including the inductor LP2 and the inductor LN2). In some embodiments, the first capacitor pair (including the capacitor C_{ESDP} and the capacitor C_{ESDN}) includes the parasitic capacitance generated when electrostatic discharge (ESD) diodes are electrically connected to the node pair (including the node A and the node B) respectively.

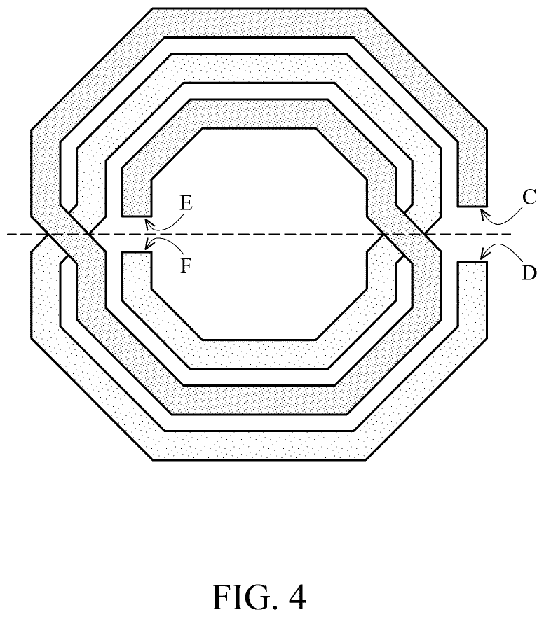

FIG. 4 shows a schematic diagram of an inductor pair including an inductor LP and an inductor LN in accordance with some embodiments of the present invention. The inductor pair in FIG. 4 may be, for example, the inductor LP and the inductor LN of the high-frequency impedance matching circuit 306 in FIG. 3. For example, the inductor LP is electrically connected between a node E and a node C. The inductor LN is electrically connected between a node F and a node D. In some embodiments of FIG. 4, the layout shape of the inductor LP and the inductor LN can be, for example, an octagonal spiral shape, but the present invention is not limited thereto. The layout shape of the inductor LP and the inductor LN can also be designed as a circular spiral shape, a hexagonal spiral shape, etc., as long as there is a coupling effect between the inductor LP and the inductor LN.

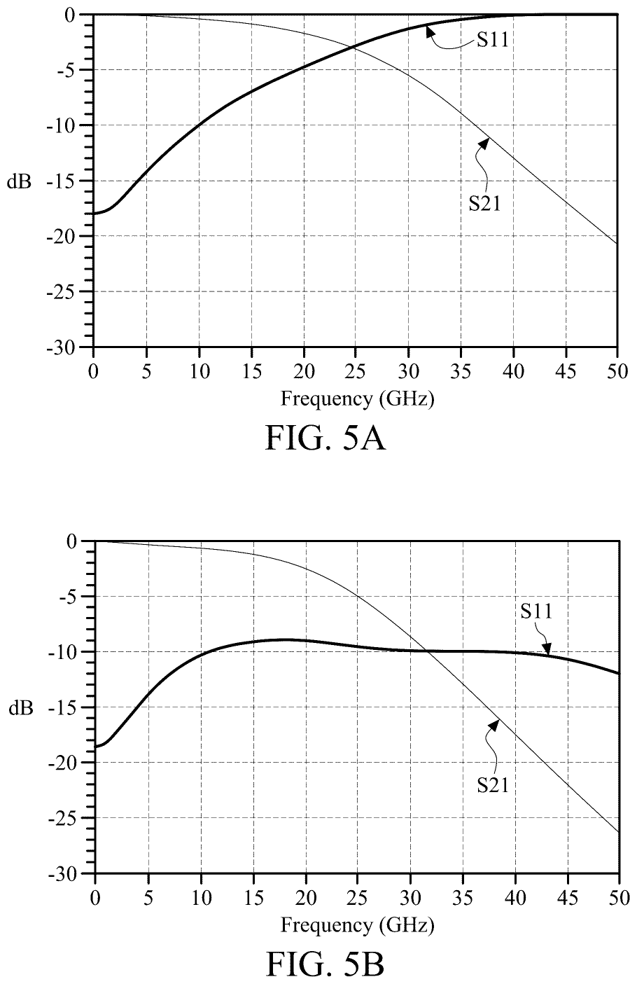

FIG. 5A shows a graph of a return loss S11 and a penetration loss S21 of the T-coil 200 in the prior art. As shown in FIG. 5A, the return loss S11 of the T-coil 200 increases to 3 dB at the frequency of 25 GHz. In other words, the energy of high-frequency signals higher than 25 GHz will be reflected after being input to the T-coil 200, resulting in poor impedance matching.

FIG. 5B shows a graph of a return loss S11 and a penetration loss S21 of the electronic device 100 in FIG. 1 and the electronic device 300 in FIG. 3 in accordance with some embodiments of the present invention. As shown in FIG. 5B, due to the arrangement of the high-frequency impedance matching circuits 106 and 306, the return loss S11 of the electronic device 100 and the electronic device 300 can be maintained at 10 dB from above 25 GHz to 50 GHz. In other words, after the high-frequency signals higher than 25 GHz are input to the electronic device 100 and the electronic device 300, almost no energy is reflected. That is, the electronic device 100 and the electronic device 300 have a very significant improvement in the return loss S11 of the high-frequency signals compared with the T-coil 200.

The high-frequency impedance matching circuit 106 of the electronic device 100 and the high-frequency impedance matching circuit 306 of the electronic device 300 of the present invention can effectively improve the high-frequency response of the entire transmission line, making the basic bandwidth of the entire transmission line larger. In addition, only the receiving circuit 108 is connected in series to the nodes A and B in the bandwidth expansion circuit 104 and the bandwidth expansion circuit 304, and the transmitting circuit 110 is connected in series to the subsequent stages of the bandwidth expansion circuit 104 and the bandwidth expansion circuit 304, so the superposition of parasitic capacitances is reduced. Finally, the bandwidth expansion circuit 104 and the bandwidth expansion circuit 304 are used to double the basic bandwidth of the entire transmission line, so that the electronic device 100 and the electronic device 300 have good frequency response regardless of high frequency or low frequency. That is, the signals received by the electronic device 100 and the electronic device 300 can be almost completely transmitted, and the reflected part is very small.

The electronic device 100 and the electronic device 300 of the present invention can still effectively increase the signal transmission efficiency and transmission quality between the semiconductor package and its internal semiconductor chip, reduce the delay caused by the different frequency components included in the signal during signal transmission, and improve the eye pattern during signal transmission. The electronic device 300 of the present invention also effectively reduces circuit layout space through multiple inductor pairs with coupling effects. The electronic device 100 and the electronic device 300 of the present invention are suitable for high-speed and wide-band serial data transmission related applications, such as high-speed peripheral component interconnect express (PCI-E), universal serial bus (USB), and serial advanced technology attachment (SATA), but are not limited thereto.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electronic device, comprising:
a common pin pair, wherein the electronic device receives or transmits a signal through the common pin pair, and the signal is a differential signal;
a bandwidth expansion circuit, electrically coupled to the common pin pair, comprising:
a first inductor pair, electrically connected between the common pin pair and a node pair;
a second inductor pair, electrically connected to the first inductor pair through the node pair;
a first capacitor pair, electrically connected between the node pair and a ground end;
a second capacitor pair, electrically connected to the common pin pair and the ground end; and
a third capacitor pair, electrically connected between the second inductor pair and the ground end,
wherein the first inductor pair comprises a first inductor and a second inductor, and the second inductor pair comprises a third inductor and a fourth inductor;
wherein there is a coupling effect between the first inductor and the second inductor, and there is a coupling effect between the third inductor and the fourth inductor.

2. The electronic device as claimed in claim 1, further comprising:
a high-frequency impedance matching circuit, electrically connected between the common pin pair and the bandwidth expansion circuit, comprising:
a third inductor pair, electrically connected between the common pin pair and the bandwidth expansion circuit;
a fourth capacitor pair, electrically connected to one side of the third inductor pair;
a fifth capacitor pair, electrically connected to the other side of the third inductor pair;
a first resistor pair, electrically connected between the fourth capacitor pair and the ground end; and
a second resistor pair, electrically connected between the fifth capacitor pair and the ground end;
wherein the third inductor pair comprises a fifth inductor and a sixth inductor, and there is a coupling effect between the fifth inductor and the sixth inductor.

3. The electronic device as claimed in claim 2, further comprising:
a switch pair, electrically connected to the second inductor pair;
a terminal resistor pair, electrically connected between the switch pair and the ground end;
wherein when the electronic device receives the signal through the common pin pair, the switch pair is turned on;
wherein when the electronic device transmits the signal through the common pin pair, the switch pair is turned off.

4. The electronic device as claimed in claim 1, further comprising:
a receiving circuit, electrically connected to the node pair, configured to receive the signal from the common pin pair.

5. The electronic device as claimed in claim 1, further comprising:
a transmitting circuit, electrically connected to the second inductor pair, configured to transmit the signal to the common pin pair.

6. The electronic device as claimed in claim 1, wherein the first inductor generates an equivalent inductance based on the coupling effect, and the equivalent inductance is obtained using an equation:
L_{eff1}=L₁*(1+kₛ₁);
wherein L_{eff1} is the equivalent inductance, L₁ is an inductance of the first inductor, and kₛ₁ is a coupling coefficient between the first inductor and the second inductor; the coupling coefficient is greater than zero.

7. The electronic device as claimed in claim 4, wherein the first capacitor pair comprises a parasitic capacitance generated when the receiving circuit is electrically connected to the node pair.

8. The electronic device as claimed in claim 5, wherein the third capacitor pair comprises a parasitic capacitance generated when the transmitting circuit is electrically connected to the second inductor pair.

9. The electronic device as claimed in claim 4, wherein the first capacitor pair comprises a parasitic capacitance generated when electrostatic discharge (ESD) diodes are respectively electrically connected to the node pair.

10. The electronic device as claimed in claim 1, wherein the node pair is a pair of pins in a semiconductor package;
wherein the semiconductor package comprises a semiconductor chip.

11. The electronic device as claimed in claim 10, wherein the node pair is a pair of pins in the semiconductor chip;
wherein the first inductor pair and the second inductor pair are bonding wires for electrically connecting to the common pin pair.

12. The electronic device as claimed in claim 3, wherein the signal comprises a high-frequency component signal and a low-frequency component signal;
wherein when the electronic device receives the signal through the common pin pair, the high-frequency component signal terminates at the first resistor pair, and the low-frequency component signal terminates at the terminal resistor pair.
